(19) United States
(12) Patent Application Publication
(10) Pub. No.: US 2025/0015136 A1
(43) Pub. Date: Jan. 9, 2025

(54) NITRIDE SEMICONDUCTOR DEVICE

(71) Applicant: ROHM CO., LTD., Kyoto-shi (JP)

(72) Inventor: Ryoichi MAKINO, Kyoto-shi (JP)

(73) Assignee: ROHM CO., LTD., Kyoto-shi (JP)

(21) Appl. No.: 18/895,404

(22) Filed: Sep. 25, 2024

Related U.S. Application Data
(63) Continuation of application No. PCT/JP2023/006474, filed on Feb. 22, 2023.

(30) Foreign Application Priority Data
Mar. 30, 2022 (JP) 2022-057076

(51) Int. Cl. H01L 29/10; H01L 29/423; H01L 29/778; H01L 29/20; H01L 29/40

(52) U.S. Cl. CPC H01L 29/1066; H01L 29/42316; H01L 29/7787; H01L 29/2003; H01L 29/402

(57) ABSTRACT

A nitride semiconductor device includes an electron transit layer, an electron supply layer disposed on the electron transit layer to generate two-dimensional electron gas in the electron transit layer, a gate layer containing acceptor impurities and disposed on the electron supply layer, a gate electrode contacting the gate layer, a source electrode, and a drain electrode. The gate layer includes a trench that is recessed from an upper surface of the gate layer in a region contacting the gate electrode. The trench includes a trench open end, a trench bottom surface, and a curved surface continuous with the trench bottom surface and curved from the trench bottom surface toward the trench open end.

### CROSS-REFERENCE TO RELATED APPLICATIONS

This is a continuation application of PCT/Application No. PCT/JP2023/006474, filed on Feb. 22, 2023, which claims priority to Japanese Patent Application No. 2022-057076, filed on Mar. 30, 2022, the entire contents of each of which are incorporated herein by reference.

### BACKGROUND

### 1. Field

This disclosure relates to a nitride semiconductor device.

### 2. Description of Related Art

High-electron-mobility transistors (HEMTs) are now being commercialized. A HEMT uses a group III nitride semiconductor (hereafter, simply referred to as nitride semiconductor), such as gallium nitride (GaN). A HEMT uses two-dimensional electron gas (2 DEG) formed near a semiconductor heterojunction interface as a conduction path (channel). A power device using a HEMT has a lower ON resistance and is operable at a higher speed and higher frequency than a typical silicon (Si) power device.

For example, a nitride semiconductor HEMT includes an electron transit layer, which is formed by a gallium nitride (GaN) layer, and an electron supply layer, which is formed by an aluminum gallium nitride (AlGaN) layer. The 2 DEG is formed in the electron transit layer near the heterojunction interface of the electron transit layer and the electron supply layer. In a normally-off type HEMT, for example, a semiconductor layer (e.g., p-type GaN layer) containing acceptor impurities is arranged on the electron transit layer underneath a gate electrode. In this structure, a depletion layer spreading downward from the gate layer depletes the channel located underneath the gate layer and obtains a normally-off state. Japanese Laid-Open Patent Publication No. 2017-73506 discloses a nitride semiconductor HEMT of a normally-off type.

### BRIEF DESCRIPTION OF THE DRAWINGS

FIG. 1 is a schematic cross-sectional view of an exemplary nitride semiconductor device in accordance with a first embodiment.

FIG. 2 is a partially enlarged cross-sectional view of the nitride semiconductor device of FIG. 1 illustrating an exemplary structure of a gate layer, which includes a trench, and a gate electrode.

FIG. 3 is a partially enlarged cross-sectional view of FIG. 2.

FIG. 4 is a partially enlarged cross-sectional view illustrating a feasible structure of the gate electrode.

FIG. 5 is a diagram illustrating a simulation result of the electric field distribution (equipotential lines) in the periphery of the gate electrode in the nitride semiconductor device of FIG. 1.

FIG. 6 is a diagram illustrating a simulation result of the electric field distribution (equipotential lines) in the periphery of a gate electrode in a typical nitride semiconductor device having no trenches.

FIG. 7 is a graph illustrating the gate breakdown voltage characteristic of the nitride semiconductor device illustrated in FIG. 1 and the gate breakdown voltage characteristic of the nitride semiconductor device illustrated in FIG. 6.

FIG. 8 is a graph illustrating the maximum electric field intensity of the nitride semiconductor device illustrated in FIG. 1 and the maximum electric field intensity of the nitride semiconductor device illustrated in FIG. 6.

FIG. 9 is a graph illustrating the relationship of a gate electrode (projection) width, trench depth, and maximum electric field intensity in the nitride semiconductor device of FIG. 1.

FIG. 10 is a graph illustrating the relationship of a gate electrode (projection) width, radius of curvature of curved surface, and maximum electric field intensity in the nitride semiconductor device of FIG. 1.

FIG. 11 is a schematic cross-sectional view of an exemplary nitride semiconductor device in accordance with a second embodiment, and illustrates a case in which a trench wall surface of a gate layer includes a vertical surface.

FIG. 12 is a schematic cross-sectional view of an exemplary nitride semiconductor device in accordance with the second embodiment, and illustrates a case in which the trench wall surface of the gate layer includes an inclined surface.

FIG. 13 is a schematic cross-sectional view of an exemplary nitride semiconductor device in accordance with the second embodiment, and illustrates a case in which the trench wall surface of the gate layer includes a further moderately inclined surface.

### DETAILED DESCRIPTION

Several embodiments of a semiconductor device in accordance with the present disclosure will now be described with reference to the accompanying drawings. In the drawings, elements are illustrated for simplicity and clarity and have not necessarily been drawn to scale. To aid understanding, hatching lines may not be shown in the cross-sectional drawings. The accompanying drawings illustrate exemplary embodiments in accordance with the present disclosure and are not intended to limit the present disclosure.

This detailed description provides a comprehensive understanding of exemplary methods, apparatuses, and/or systems in accordance with the present disclosure. This detailed description is illustrative and is not intended to limit embodiments of the present disclosure or the application and use of the embodiments.

### FIRST EMBODIMENT

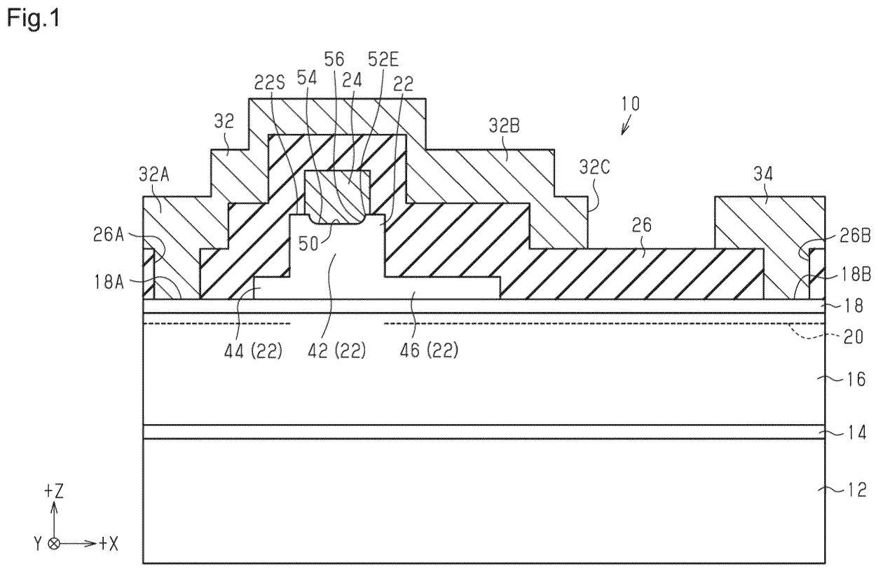

FIG. 1 is a schematic cross-sectional view of an exemplary nitride semiconductor device 10 in accordance with a first embodiment. With reference to FIG. 1, the overall structure of the nitride semiconductor device 10 will now be described.

### Overall Structure of Nitride Semiconductor Device

The nitride semiconductor device 10 may be, for example, a high-electron-mobility transistor (HEMT) that uses a nitride semiconductor such as gallium nitride (GaN). The nitride semiconductor device 10 includes a substrate 12, a buffer layer 14 formed on the substrate 12, an electron transit layer 16 formed on the buffer layer 14, and an electron supply layer 18 formed on the electron transit layer 16.

The substrate 12 may be formed from silicon (Si), silicon carbide (SiC), aluminum nitride (AlN), GaN, sapphire, or other substrate materials. For example, the substrate 12 is a Si substrate. The substrate 12 may have a thickness of, for example, 200 μm or greater and 1500 μm or less. FIG. 1 indicate X, Y, and Z axes that are orthogonal to one another. The direction of the Z-axis is orthogonal to a main surface of the substrate 12. Unless otherwise indicated, the term “plan view” as used in this specification will refer to a view of the nitride semiconductor device 10 taken from above in the Z-axis direction.

The buffer layer 14, which is located between the substrate 12 and the electron transit layer 16, may be formed from any material that reduces lattice mismatching between the substrate 12 and the electron transit layer 16. The buffer layer 14 may include, for example, one or more nitride semiconductor layers. For example, the buffer layer 14 may include at least one of an AlN layer, an aluminum gallium nitride (AlGaN) layer, and a graded AlGaN layer having different aluminum (Al) compositions. For example, the buffer layer 14 may include a single AlN layer, a single AlGaN layer, a layer having an AlGaN/GaN superlattice structure, a layer having an AlN/AlGaN superlattice structure, or a layer having an AlN/GaN superlattice structure.

In one example, the buffer layer 14 includes a first buffer layer that is formed on the substrate 12 and a second buffer layer that is formed on the first buffer layer. The first buffer layer is, for example, an AlN layer and may have a thickness of, for example, approximately 200 nm. The second buffer layer includes, for example, multiple AlGaN layers, and each AlGaN layer may have a thickness of, for example, approximately 100 nm. To reduce leakage current in the buffer layer 14, part of the buffer layer 14 may be doped with impurities to be semi-insulating. In this case, the impurities may be carbon (C) or iron (Fe), and the concentration of the impurities may be, for example, 4×10¹⁶ cm⁻³ or greater.

The electron transit layer 16 is composed of a nitride semiconductor and may be, for example, a GaN layer. The electron transit layer 16 may have a thickness of, for example, 0.5 m or greater and 2 μm or less. To reduce leakage current in the electron transit layer 16, part of the electron transit layer 16 may be doped with impurities so that regions other than the outermost part of the electron transit layer 16 is semi-insulating. In this case, the impurities are, for example, carbon (C). The concentration of the impurities may be, for example, greater than or equal to 1×10¹⁹ cm⁻³ at a peak concentration.

The electron supply layer 18 is composed of a nitride semiconductor having a larger band gap than the electron transit layer 16 and may be, for example, an AlGaN layer. In an AlGaN layer, the band gap will become larger as the Al composition increases. Thus, the electron supply layer 18, which is an AlGaN layer, will have a larger band gap than the electron transit layer 16, which is a GaN layer. For example, the electron supply layer 18 is composed of AlₓGa₁₋ₓN, where x is 0.1<x<0.4 is satisfied, and, further preferably, 0.2<x<0.3 is satisfied, although there is no limitation to such a range. The electron supply layer 18 may have a thickness of, for example, 5 nm or greater and 20 nm or less.

The electron transit layer 16 and the electron supply layer 18 may be composed of nitride semiconductors having different lattice constants. Thus, the nitride semiconductor (e.g., GaN) of the electron transit layer 16 and the nitride semiconductor (e.g., AlGaN) of the electron supply layer 18 form a lattice-mismatched junction. The spontaneous polarization of the electron transit layer 16 and the electron supply layer 18 and the piezoelectric polarization resulting from the stress received by the heterojunction of the electron supply layer 18 cause the energy level of the conduction band of the electron transit layer 16 to be lower than the Fermi level in the proximity of the heterojunction interface between the electron transit layer 16 and the electron supply layer 18. Thus, a two-dimensional electron gas (2 DEG) 20 spreads in the electron transit layer 16 at a position proximate to the heterojunction interface of the electron transit layer 16 and the electron supply layer 18 (e.g., distanced by approximately a few nanometers from interface).

The nitride semiconductor device 10 further includes a gate layer 22 formed on the electron supply layer 18, a gate electrode 24 formed on the gate layer 22, and a passivation layer 26. The passivation layer 26 covers the electron supply layer 18, the gate layer 22, and the gate electrode 24.

The gate layer 22 is composed of a nitride semiconductor containing acceptor impurities and is formed on the electron supply layer 18. The gate layer 22 may be formed from any material having a smaller band gap than the electron supply layer 18. For example, when the electron supply layer 18 is an AlGaN layer, the gate layer 22 may be a GaN layer doped with acceptor impurities, that is, a p-type GaN layer. The acceptor impurities may include, for example, at least one of zinc (Zn), magnesium (Mg), and carbon (C). The maximum concentration of the acceptor impurities is, for example, 7×10¹⁸ cm⁻³ or greater and 1×10²⁰ cm⁻³ or less.

The gate electrode 24 and the gate layer 22 form a Schottky junction. The gate electrode 24, which includes one or more metal layers, may be, for example, a titanium nitride (TiN) layer. Alternatively, the gate electrode 24 may include a first metal layer (e.g., Ti layer) and a second metal layer (e.g., TiN layer) arranged on the first metal layer. The gate electrode 24 may have a thickness, from an upper surface 22S of the gate layer 22 to an upper surface of the gate electrode 24, of, for example, 50 nm or greater and 300 nm or less. In a structure in which a nitride semiconductor layer containing acceptor impurities and serving as the gate layer 22 is located directly under the gate electrode 24, the acceptor impurities contained in the gate layer 22 deplete the channel (2 DEG 20) in the electron transit layer 16. This results in the nitride semiconductor HEMT being of a normally-off type.

The passivation layer 26 is formed by, for example, a single film that is any one of a silicon nitride (SiN) film, a silicon dioxide (SiO₂) film, a silicon oxynitride (SiON) film, an alumina (Al₂O₃) film, an AlN film, and an aluminum oxynitride (AlON) film or is a composite film combining two or more of these films.

The passivation layer 26 includes a first opening 26A, which exposes the upper surface of the electron supply layer 18 as a source connection region 18A, and a second opening 26B, which exposes the upper surface of the electron supply layer 18 as a drain connection region 18B. The gate layer 22 is located between the first opening 26A and the second opening 26B.

The nitride semiconductor device 10 further includes a source electrode 32 and a drain electrode 34. The source electrode 32 is in contact with the source connection region 18A of the electron supply layer 18 through the first opening 26A of the passivation layer 26 and is in ohmic contact with the 2 DEG 20 located immediately under the electron supply layer 18. The drain electrode 34 is in contact with the drain connection region 18B of the electron supply layer 18 through the second opening 26B of the passivation layer 26 and is in ohmic contact with the 2 DEG 20 located immediately under the electron supply layer 18.

The source electrode 32 and the drain electrode 34 are formed by, for example, one or more metal layers including at least one of a Ti layer, TiN layer, an Al layer, an AlSiCu layer, and an AlCu layer. For example, the source electrode 32 and the drain electrode 34 are formed from the same material.c

As illustrated in FIG. 1, the gate layer 22 may have a stepped structure although this is not a limitation. In one example, the gate layer 22 includes a ridge 42, a source-side extension 44, and a drain-side extension 46. The source-side extension 44 and the drain-side extension 46 extend from opposite sides of the ridge 42. The ridge 42, the source-side extension 44, and the drain-side extension 46 form the stepped structure of the gate layer 22.

The ridge 42 corresponds to the relatively thick part of the gate layer 22. The gate electrode 24 is in contact with the ridge 42. The ridge 42 may have a rectangular or trapezoidal cross section taken along an XZ plane in FIG. 1. The ridge 42 may have a thickness of, for example, 100 nm or greater and 200 nm or less. The thickness of the ridge 42 refers to the distance from the upper surface of the ridge 42 to the lower surface of the ridge 42 (lower surface of gate layer 22 contacting electron supply layer 18). The thickness of the ridge 42 (gate layer 22) is determined while taking into consideration various parameters such as the gate breakdown voltage.

The source-side extension 44 extends from the ridge 42 toward the first opening 26A of the passivation layer 26 (−X direction in FIG. 1). The drain-side extension 46 extends from the ridge 42 toward the second opening 26B of the passivation layer 26 (+X direction in FIG. 1). In the example of FIG. 1, the drain-side extension 46 extends from the ridge 42 over a longer amount than the source-side extension 44. The source-side extension 44 may, however, have the same length as the drain-side extension 46. The source-side extension 44 may have a length of, for example, 0.2 μm or greater and 0.3 μm or less in the direction extending from the ridge 42 toward the first opening 26A. The drain-side extension 46 may have a length of, for example, 0.2 μm or greater and 0.6 μm or less in the direction extending from the ridge 42 toward the second opening 26B. The source-side extension 44 and the drain-side extension 46 may each have a thickness of, for example, 5 nm or greater and 30 nm or less.

The first opening 26A of the passivation layer 26 is filled with part of the source electrode 32, and the second opening 26B of the passivation layer 26 is filled with part of the drain electrode 34.

The source electrode 32 may include a source electrode portion 32A and a source field plate portion 32B continuous with the source electrode portion 32A although this is not a limitation. The source electrode portion 32A includes a filling region, which fills the first opening 26A, and an upper region formed integrally with the filling region and located proximate to the first opening 26A in plan view. The source field plate portion 32B is formed integrally with the upper region of the source electrode portion 32A and is arranged on the passivation layer 26 so as to hide the entire gate layer 22 (ridge 42, source-side extension 44, and drain-side extension 46 in example of FIG. 1) in plan view.

The source field plate portion 32B includes an end 32C in the vicinity of the drain electrode 34. The end 32C is located between the drain electrode 34 and the drain-side extension 46 in plan view. The source field plate portion 32B functions to limit electric field concentration near the end of the gate electrode 24 and in the vicinity of the end of the gate layer 22 by expanding the depletion layer toward the 2 DEG 20 underneath the source field plate portion 32B when high voltage is applied between the source and drain in a state in which the gate-source voltage is 0 V.

### Exemplary Structure of Gate Layer, Including Trench, and Gate Electrode

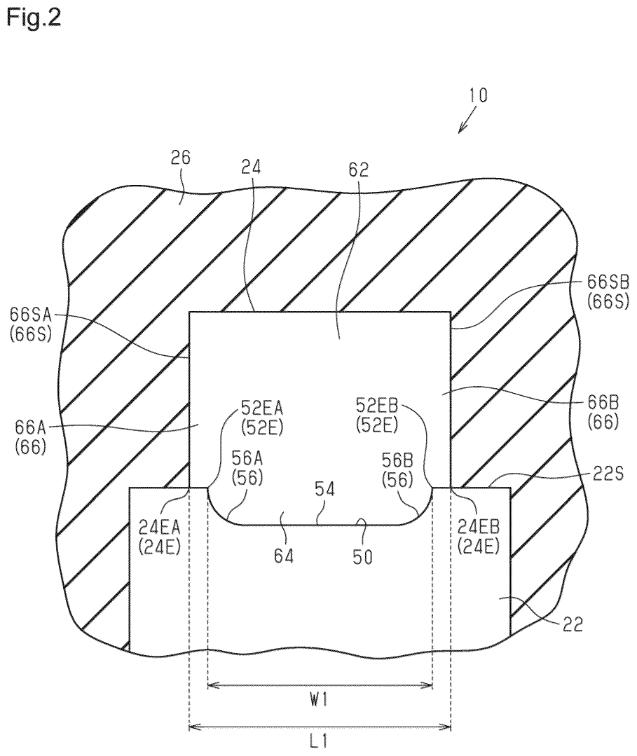

FIG. 2 is an enlarged cross-sectional view illustrating part of the nitride semiconductor device 10 illustrated in FIG. 1.

As illustrated in FIG. 2, the gate layer 22 includes a trench 50 that is recessed from the upper surface 22S of the gate layer 22 in a region contacting the gate electrode 24. The trench 50 includes a trench open end 52E, a trench bottom surface 54, and a curved surface 56, which is continuous with the trench bottom surface 54 and curved from the trench bottom surface 54 toward the trench open end 52E. The trench 50 is not particularly limited in shape. In the example of FIG. 2, the trench 50 has a bowl-shaped cross section.

The trench open end 52E of the trench 50 includes a first edge 52EA and a second edge 52EB facing each other in a first direction. The first direction corresponds to the X-direction in FIG. 1 and is the direction in which the source electrode 32 (first opening 26A), the gate layer 22, and the drain electrode 34 (second opening 26B) are arranged next to one another in FIG. 1. The trench 50 has a trench width W1 corresponding to the distance between the first edge 52EA and the second edge 52EB in the first direction. The curved surface 56 of the trench 50 includes a first curved surface 56A, which is curved from the trench bottom surface 54 toward the first edge 52EA, and a second curved surface 56B, which is curved from the trench bottom surface 54 toward the second edge 52EB. The gate electrode 24 has a gate electrode length L1 in the first direction. The trench 50 (gate layer 22) and the gate electrode 24 are formed so that the trench width W1 is less than or equal to the gate electrode length L1.

The gate electrode 24 includes an upper electrode portion 62 and a lower electrode portion 64. The lower electrode portion 64 corresponds to the lower region of the gate electrode 24 that fills the trench 50. The upper electrode portion 62 corresponds to the upper region of the gate electrode 24 formed integrally with the lower electrode portion 64 and located upward from the upper surface 22S of the gate layer 22.

In the example of FIG. 2, the trench width W1 is less than the gate electrode length L1. In this case, the upper electrode portion 62 includes a projection 66 projecting sideways from the trench open end 52E along the upper surface 22S of the gate layer 22. The projection 66 includes a first projection 66A, which projects sideways from the first edge 52EA of the trench open end 52E along the upper surface 22S of the gate layer 22, and a second projection 66B, which projects sideways form the second edge 52EB of the trench open end 52E along the upper surface 22S of the gate layer 22.

Thus, in the example of FIG. 2, the gate electrode 24 includes a first electrode end 24EA and a second electrode end 24EB that contact the upper surface 22S of the gate layer 22. In the description hereafter, the first electrode end 24EA and the second electrode end 24EB will collectively be referred to as the electrode end 24E as long as they are not distinguished from each other. The first electrode end 24EA corresponds to the lower end of a side surface 66SA of the first projection 66A, and the second electrode end 24EB corresponds to the lower end of a side surface 66SB of the second projection 66B.

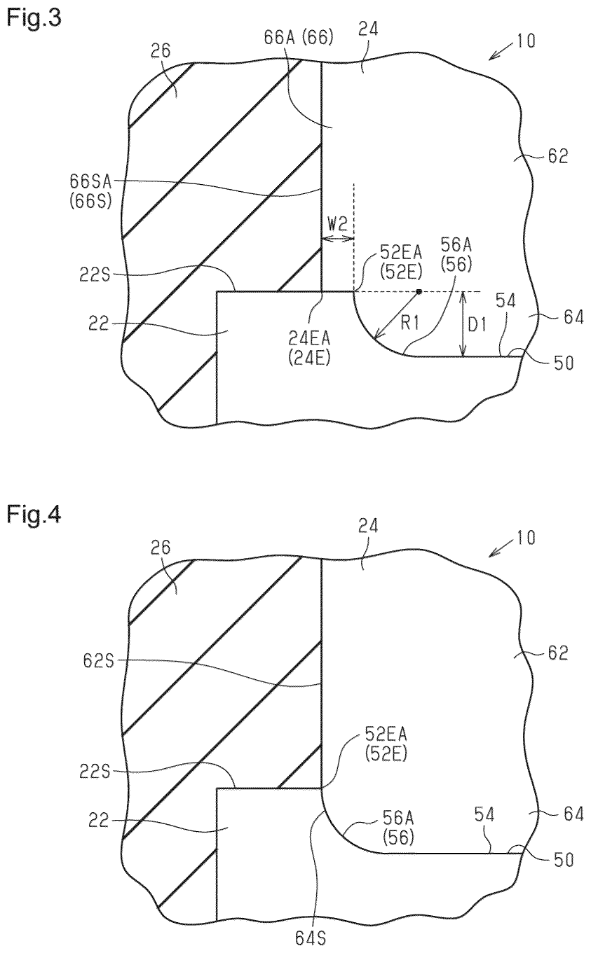

With reference to FIGS. 3 and 4, the structural relationship of the trench 50 (gate layer 22) and the gate electrode 24 will now be described. FIG. 3 is a partially enlarged cross-sectional view of FIG. 2. FIG. 4 is a partially enlarged cross-sectional view illustrating a feasible structure of the gate electrode 24.

As illustrated in FIG. 3, the trench 50 has depth D1, and the first curved surface 56A (curved surface 56) has radius of curvature R1. Although FIG. 3 illustrates only the first curved surface 56A, the same applies to the second curved surface 56B. The depth D1 corresponds to the distance from the trench open end 52E to the trench bottom surface 54 in a direction orthogonal to the upper surface 22S of the gate layer 22.

In the example of FIG. 3, the upper electrode portion 62 of the gate electrode 24 includes the first projection 66A projecting sideways from the first edge 52EA of the trench open end 52E along the upper surface 22S of the gate layer 22 over projection width W2. Thus, the gate electrode 24 includes the first electrode end 24EA (electrode end 24E) that contacts the upper surface 22S of the gate layer 22. Although FIG. 3 illustrates only the first projection 66A, the same applies to the second projection 66B.

The depth D1 of the trench 50, the radius of curvature R1 of the curved surface 56, the projection width W2 of the projection 66, and a combination of these parameters may be set to mitigate local electric field concentration at the gate layer 22. For example, the values of the depth D1, the radius of curvature R1, and the projection width W2 are selected to obtain a greater electric field mitigation effect than with a typical gate layer having no trench structure. The electric field mitigation effect obtained with the gate layer 22 that has a trench structure (trench 50 including curved surface 56) will be described later.

In one example, the depth D1 may be, for example, 10 nm or greater and 50 nm or less. The radius of curvature R1 may be, for example, 5 nm or greater and 30 nm or less. Further, the projection width W2 may be, for example, greater than 0 and less than or equal to 100 nm. The depth D1, the radius of curvature R1, and the projection width W2 are not necessarily limited to such ranges and may be set in other ranges that obtain the electric field mitigation effect.

FIG. 4 illustrates a structure in which the projection width W2 of the projection 66 is 0 nm (i.e., gate electrode 24 has no projection 66). In this manner, the gate electrode 24 does not have to include the projection 66. In this structure, the upper electrode portion 62 includes a side surface 62S that is flatly continuous with an outer surface 64S of the lower electrode portion 64 at where the trench open end 52E (in FIG. 4, first edge 52EA) is located. Accordingly, the gate electrode 24 of FIG. 4 does not include the electrode end 24E of the gate electrode 24 illustrated in FIG. 3.

### Electric Field Mitigation Effect Obtained by Trench Structure

The electric field mitigation effect obtained with the gate layer 22 including the trench structure (trench 50 including curved surface 56) will now be described.

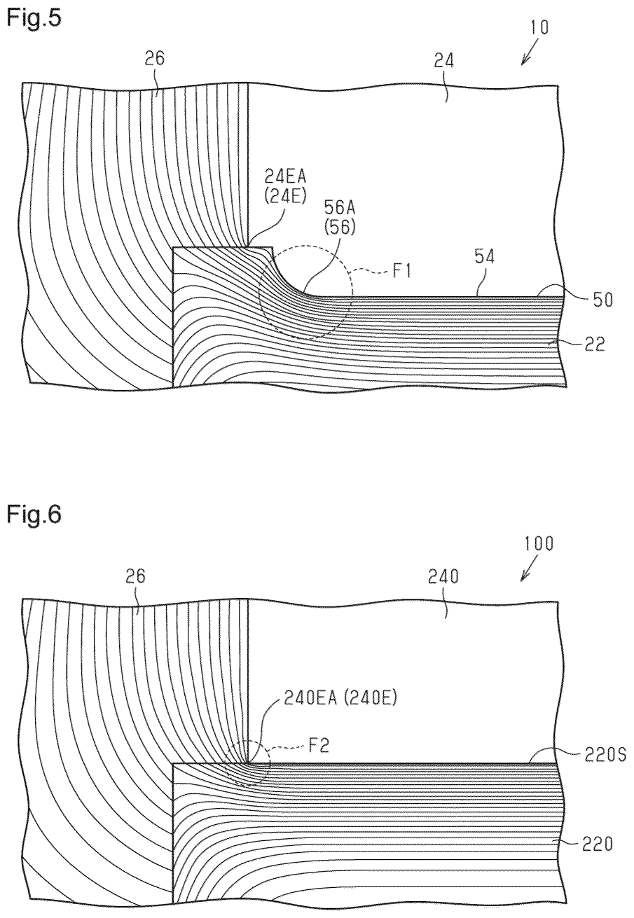

FIG. 5 is a diagram illustrating a simulation result of the electric field distribution (equipotential lines) in the periphery of the gate electrode 24 in the nitride semiconductor device 10 of FIG. 1. The structure of FIG. 5 corresponds to the structure of FIG. 3. The simulation results represent the electric field distribution when, for example, a gate voltage of 10 V is applied to the gate electrode 24. As illustrated in FIG. 5, in the structure of the gate layer 22 that includes the trench 50, the electric field (equipotential lines) is concentrated at region F1 where the curved surface 56 (in FIG. 5, first curved surface 56A) of the trench 50 is located.

FIG. 6 is a diagram illustrating a simulation result of the electric field distribution (equipotential lines) in the periphery of a gate electrode 240 in a typical nitride semiconductor device 100 including a gate layer 220 having no trench structure. The structure of FIG. 6 is an example compared with the structure of FIG. 5. The gate layer 220 includes a flat upper surface 220S and does not include the trench 50 illustrated in FIG. 5. The gate electrode 240 is located on the upper surface 220S of the gate layer 220 and includes an electrode end 240E (first electrode end 240EA in FIG. 6) that contacts the upper surface 220S. As illustrated in FIG. 6, in the structure of the gate layer 220 having no trench structure, the electric field (equipotential lines) is concentrated in the gate layer 220 at region F2 that is proximate to the electrode end 240E of the gate electrode 240.

In comparison with the structure of FIG. 6 in which the electric field concentrates locally at region F2 (vicinity of electrode end 240E) in the gate layer 220, the electric field in the structure of FIG. 5 concentrates over a wider range in region F1 where the curved surface 56 is located and the electric field does not concentrate at the region in the gate layer 22 that is proximate to the electrode end 24E. Thus, in contrast with the structure of FIG. 6, the structure of FIG. 5 mitigates the electric field that forms in the gate layer 22.

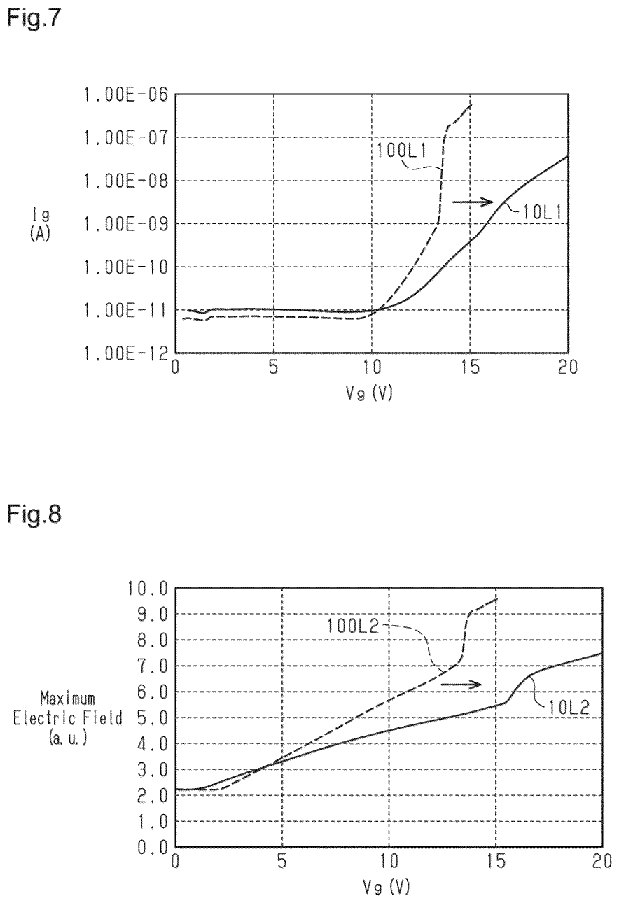

FIG. 7 is a graph illustrating the gate breakdown voltage characteristic of the nitride semiconductor device 10 illustrated in FIG. 1, and the gate breakdown voltage characteristic of the nitride semiconductor device 100 illustrated in FIG. 6. In FIG. 7, graph 10L1 of the solid line illustrates the gate breakdown voltage characteristic of the nitride semiconductor device 10, and graph 100L1 of the broken line illustrates the gate breakdown voltage characteristic of the nitride semiconductor device 100. The horizontal axis represents the gate voltage Vg, and the vertical axis represents the gate current Ig.

As illustrated in graph 100L1, in the nitride semiconductor device 100 of FIG. 6 (with gate layer 220 having no trench structure), breakdown occurs when the gate voltage Vg is approximately 13 V. In contrast, as illustrated in graph 10L1, in the nitride semiconductor device 100 of FIG. 1 (with gate layer 22 having trench 50 including curved surface 56), the gate current Ig increases as the gate voltage Vg increases, and an apparent breakdown does not occur. Further, the increase rate of the gate current Ig decreases. Accordingly, in the nitride semiconductor device 10 of FIG. 1, the gate breakdown voltage characteristic is improved from the nitride semiconductor device 100 of FIG. 6.

FIG. 8 is a graph illustrating the maximum electric field intensity of the nitride semiconductor device 10 illustrated in FIG. 1, and the maximum electric field intensity of the nitride semiconductor device 100 illustrated in FIG. 6. In FIG. 8, graph 10L2 of the solid line illustrates the maximum electric field intensity of the nitride semiconductor device 10, and graph 100L2 of the broken line illustrates the maximum field intensity of the nitride semiconductor device 100. In this specification, the maximum electric field intensity refers to the electric field intensity at the location where the applied electric field is maximum.

The two graphs 10L2 and 100L2 illustrate that the maximum electric field intensity (i.e., applied maximum electric field) in the nitride semiconductor device 10 of FIG. 1 is less than that of the nitride semiconductor device 100 of FIG. 6. As described above, in the nitride semiconductor device 100 of FIG. 6, the maximum electric field is applied to region F2 (vicinity of electrode end 240E) in the gate layer 220. Thus, graph 100L2 illustrates the electric field intensity in region F2 (vicinity of electrode end 240E).

In the nitride semiconductor device 10 of FIG. 1, the maximum electric field is applied to region F1 (refer to FIG. 5) where the curved surface 56 is located. Thus, graph 10L2 illustrates the electric field intensity in region F1 where the curved surface 56 is located. In the nitride semiconductor device 10, the maximum electric field is applied to region F1 where the curved surface 56 is applied. This disperses the electric field applied to the gate layer 22 and mitigates local electric field concentration. As a result, the maximum electric field intensity is decreased in the nitride semiconductor device 10 of FIG. 1. For example, when the gate voltage Vg is 10 V, the maximum electric field applied to the nitride semiconductor device 100 (region F2) is approximately 5.69, and the maximum electric field applied to the nitride semiconductor device 10 (region F1) is approximately 4.50. Accordingly, an electric field mitigation effect is obtained.

### Relationship of Gate Electrode Projection Width, Trench Depth, and Maximum Electric Field Intensity

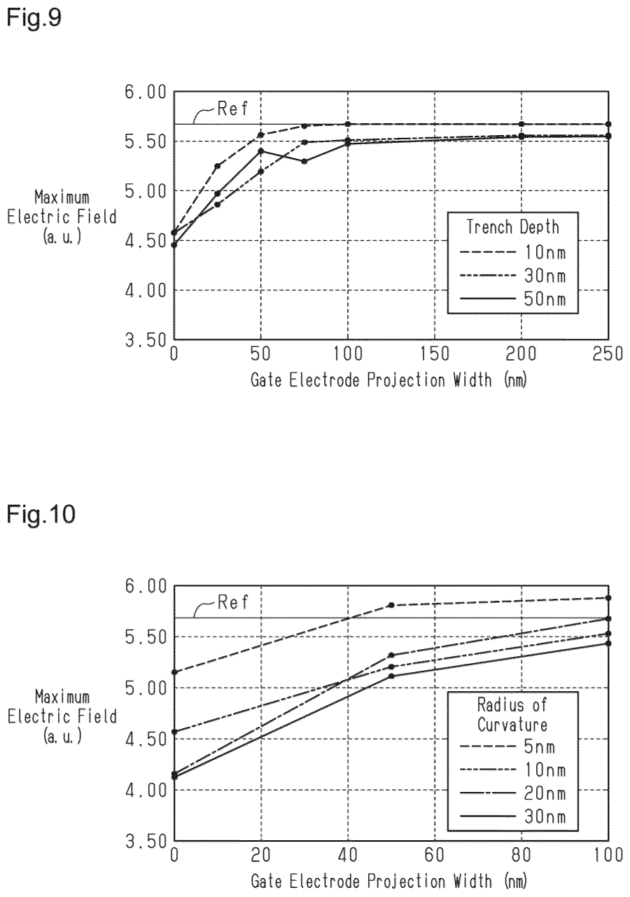

FIG. 9 is a graph illustrating the relationship of the projection width W2 of the projection 66 of the gate electrode 24 (refer to FIG. 3), the depth D1 of the trench 50 (refer to FIG. 3), and the maximum electric field intensity (maximum electric field applied to curved surface 56) in the nitride semiconductor device 10 of FIG. 1.

The example of FIG. 9 illustrates the relationship of the projection width W2 of the projection 66 and the maximum electric field applied to the curved surface 56 for three trenches 50 respectively having a depth D1 of 10 nm, 30 nm, and 50 nm. The gate voltage Vg was, for example, 10 V. Further, the projection width W2 was varied at, for example, 0 nm, 25 nm, 50 nm, 75 nm, 100 nm, 200 nm, and 250 nm. Reference value Ref indicates the maximum electric field intensity of the nitride semiconductor device 100 illustrated in FIG. 6, that is, the maximum electric field (approximately 5.69) applied to region F2 in the proximity of the electrode end 240E.

As illustrated in FIG. 9, when the depth D1 of the trench 50 is 10 nm, the maximum electric field intensity is less than the reference value Ref if the projection width W2 is 100 nm or less. When the depth D1 of the trench 50 is 30 nm or 50 nm, the maximum electric field intensity is less than the reference value Ref regardless of the projection width W2. In other words, as long as the projection width W2 is 100 nm or less, the maximum electric field intensity is less than the reference value Ref regardless of the depth D1 of the trench 50. Accordingly, the electric field mitigation effect mitigation effect is produced when the gate electrode 24 includes the projection 66, as long as the projection width W2 is greater than 0 and 100 nm or less and the depth D1 is 10 nm or greater and 50 nm or less.

The graph of FIG. 9 illustrates that the electric field mitigation effect becomes greater as the projection width W2 decreases. When the projection width W2 increases, the effect for mitigating electric field concentration at the vicinity of the electrode end 24E will becomes insufficient as the distance between the electrode end 24E and the curved surface 56 increases. When the depth D1 is small, for example, when the depth D1 is 10 nm, the electric field mitigation effect is weaker than when the depth D1 is 30 nm or 50 nm. This is because the curved surface 56 of the trench 50 has the effect of dispersing the electric field over a wide range. Thus, the depth D1 is further preferably 30 nm or greater and 50 nm or less.

When the projection width W2 is 0 nm, that is, when the gate electrode 24 does not include the projection 66, the maximum electric field intensity is minimal when the depth D1 of the trench 50 is any one of 10 nm, 30 nm, and 50 nm. This indicates that the maximum electric field mitigation effect is obtained by combining the structure of the gate electrode 24 illustrated in FIG. 4 with the trench structure of the gate layer 22. Accordingly, it is preferred that the gate electrode 24 have the structure of FIG. 4 rather than the structure of FIG. 3.

### Relationship of Gate Electrode Projection Width, Curvature of Curved Surface, and Maximum Electric Field Intensity

FIG. 10 is a graph illustrating the relationship of the projection width W2 of the projection 66 of the gate electrode 24 (refer to FIG. 3), the radius of curvature R1 of the curved surface 56 (refer to FIG. 3), and the maximum electric field intensity (maximum electric field applied to curved surface 56) in the nitride semiconductor device 10 of FIG. 1.

In the example of FIG. 10, the relationship of the projection width W2 of the projection 66 and the maximum electric field applied to the curved surface 56 is illustrated for four trenches 50 including curved surfaces 56 of which the radius of curvature R1 is 5 nm, 10 nm, 20 nm, and 30 nm, respectively. The gate voltage Vg was, for example, 10 V. Further, the projection width W2 was varied, for example, to be 0 nm, 50 nm, and 100 nm. In the same manner as FIG. 9, the reference value Ref indicates the maximum electric field intensity of the nitride semiconductor device 100 illustrated in FIG. 6, that is, the maximum electric field (approximately 5.69) applied to region F2 in the proximity of the electrode end 240E.

As illustrated in FIG. 10, when the radius of curvature R1 is 5 nm, the maximum electric field intensity is less than the reference value Ref when the projection width W2 is 40 nm or less. When the radius of curvature R1 is 10 nm, 20 nm, and 30 nm, the maximum electric field intensity is less than the reference value Ref regardless of the projection width W2. Thus, when the gate electrode 24 includes the projection 66, the electric field mitigation effect is obtained as long as the projection width W2 is greater than 0 and less than or equal to 100 nm and the radius of curvature R1 is 10 nm or greater and 30 nm or less. When the gate electrode 24 includes the projection 66, the electric field mitigation effect is also obtained as long as the projection width W2 is greater than 0 and less than or equal to 40 nm and the radius of curvature R1 is 5 nm or greater and 30 nm or less.

FIG. 10 also illustrates that the electric field mitigation effect becomes greater as the projection width W2 decreases. As described above, this is because an increase in the projection width W2 increases the distance between the electrode end 24E and the curved surface 56 and causes the electric field mitigation effect to be insufficient in the proximity of the electrode end 24E. Further, when the radius of curvature R1 is small, for example, when the radius of curvature R1 is 5 nm, the electric field mitigation effect is smaller than when the radius of curvature R1 is 10 nm, 20 nm, or 30 nm. This is because a small curvature of the curved surface 56 increases the electric field concentration at the curved surface 56. Accordingly, the radius of curvature R1 is further preferably 10 nm or greater and 30 nm or less.

### Operation of Nitride Semiconductor Device

The operation of the nitride semiconductor device 10 will now be described.

The gate layer 22 of the nitride semiconductor device 10 includes the trench 50 recessed from the upper surface 22S of the gate layer 22 in a region contacting the gate electrode 24. The trench 50 includes the curved surface 56 that is curved from the trench bottom surface 54 toward the trench open end 52E. In this structure, electric field is concentrated over a wider region in the trench 50 at the curved surface 56. This limits local electric field concentration at the gate layer 22 in the vicinity of the electrode end 24E of the gate electrode 24. As a result, the electric field applied to the gate layer 22 is mitigated. In particular, in the structure of FIG. 4 in which the gate electrode 24 does not include the projection 66, the gate electrode 24 does not include the electrode end 24E that contacts the upper surface 22S of the gate layer 22. Thus, the electric field applied to the gate layer 22 is further mitigated.

The nitride semiconductor device 10 of the first embodiment has the advantages described below.
(1-1) The gate layer 22 includes the trench 50 including the curved surface 56. In this structure, electric field is concentrated over a wider region in the trench 50 at the curved surface 56. This reduces local electric field concentration at the part of the gate layer 22 in the vicinity of the electrode end 24E of the gate electrode 24 and mitigates the electric field (maximum electric field intensity) applied to the gate layer 22. As a result, crystal defect or crystal breakdown of the gate layer that would be caused by such local electric field concentration does not occur, and decreases in the gate breakdown voltage are limited.
(1-2) The trench width W1 of the trench 50 is less than or equal to the gate electrode length L1 of the gate electrode 24 (refer to FIG. 2). This structure does not decrease the area of contact of the gate electrode 24 with the gate layer 22, and maintains the capability for transmitting gate signals from the gate electrode 24 to the gate layer 22 in a satisfactory manner.
(1-3) The gate electrode 24 includes the lower electrode portion 64, which fills the trench 50, and the upper electrode portion 62, which is formed integrally with the lower electrode portion 64 and located upward from an upper surface position of the gate layer 22. In this case, the gate electrode 24 may include the side surface 62S configured so that the side surface 62S of the upper electrode portion 62 is flatly continuous with the outer surface 64S of the lower electrode portion 64 at where the trench open end 52E is located (refer to FIG. 4). In this structure, the gate electrode 24 does not include the projection 66 (refer to FIG. 3) and the electrode end 24E (refer to FIG. 3). Such a gate electrode 24 is combined with the gate layer 22 that includes the trench 50 including the curved surface 56 to further mitigate the electric field applied to the gate layer 22.
(1-4) Alternatively, the upper electrode portion 62 may include the projection 66 (refer to FIG. 3) that projects sideways from the trench open end 52E along the upper surface 22S of the gate layer 22. In the structure of such a gate electrode 24, the gate layer 22 that includes the trench 50 including the curved surface 56 also mitigates the electric field applied to the gate layer 22.
(1-5) The projection 66 may project sideways from the trench open end 52E along the upper surface 22S of the gate layer 22 over the projection width W2 that is less than the depth D1 of the trench 50. When the projection width W2 is large, the effect for mitigating electric field concentration in the proximity of the electrode end 24E may become insufficient when the distance increases between the electrode end 24E and the curved surface 56. When the relationship of W2≤D1 is satisfied, the projection width W2 is limited in accordance with the depth D1. This maintains the electric field mitigation effect in a satisfactory manner.
(1-6) The projection width W2 of the projection 66 may be greater than 0 nm and less than or equal to 100 nm. In this case, the electric field mitigation effect is obtained when, for example, the depth D1 of the trench 50 is 10 nm or greater and 50 nm or less (refer to FIG. 9). Further, for example, the electric field mitigation effect is obtained when the radius of curvature R1 of the curved surface 56 is 10 nm or greater and 30 nm or less (refer to FIG. 10). As illustrated in FIGS. 9 and 10, the electric field mitigation effect is maximized when there is no projection 66 (i.e., projection width W2 is 0 nm), the depth D1 of the trench 50 is 50 nm, and the radius of curvature R1 of the curved surface 56 is 30 nm.
(1-7) The electron transit layer 16 may be a GaN layer. In this case, the electron supply layer 18 may be an AlGaN layer. Further, the gate layer 22 may be a GaN layer containing acceptor impurities. This structure reduces the electric field (maximum electric field intensity) applied to the gate layer 22 and reduces the gate breakdown voltage in a normally-off type GaN-HEMT.

### SECOND EMBODIMENT

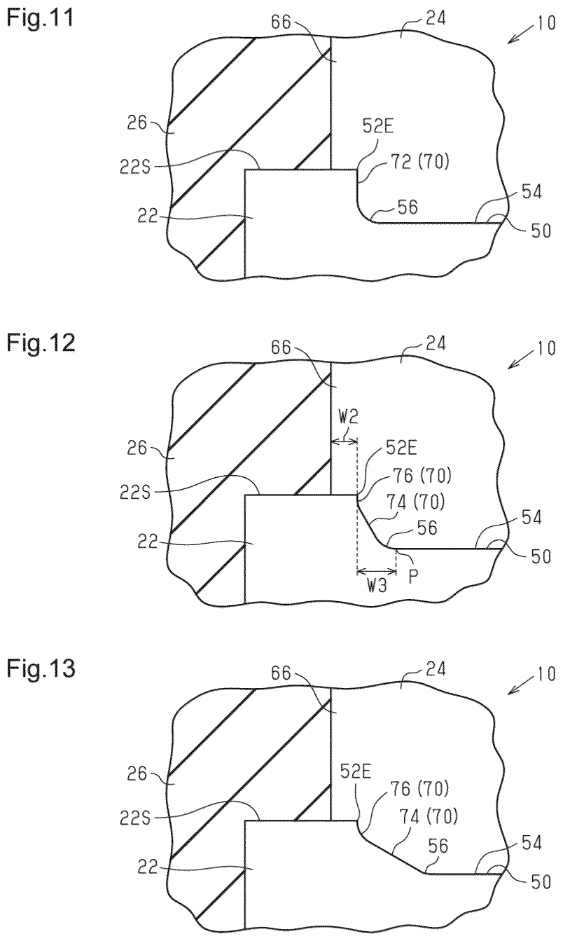

FIGS. 11 to 13 are schematic cross-sectional views of an exemplary nitride semiconductor device 10 in accordance with a second embodiment. In FIGS. 11 to 13, same reference characters are given to those elements that are the same as the corresponding elements in the nitride semiconductor device 10 of the first embodiment. Elements that are the same as the corresponding elements in the first embodiment will not be described in detail. The description will focus on differences from the first embodiment.

In the second embodiment, the trench 50 includes a trench wall surface 70 that connects the trench open end 52E and the curved surface 56. For example, as illustrated in FIG. 11, the trench wall surface 70 includes a vertical surface 72 that is orthogonal to the upper surface 22S of the gate layer 22.

Alternatively, as illustrated in FIGS. 12 and 13, the trench wall surface 70 includes an inclined surface 74 that is inclined relative to the upper surface 22S of the gate layer 22. For example, in FIG. 12, the inclined surface 74 has an inclination angle of 60°. In FIG. 13, the inclined surface 74 has a more moderate inclination angle of 30°. The inclined surface 74 may have any angle that is greater than 0° and less than 90°, preferably, 30° or greater and 60° or less. Further, as illustrated in FIGS. 12 and 13, in addition to the inclined surface 74, the trench wall surface 70 may include a second curved surface 76. The second curved surface 76 connects the inclined surface 74 and the trench open end 52E. The second curved surface 76 also has the effect for dispersing the electric field applied to the gate layer 22 and mitigating local electric field concentration. Alternatively, the trench wall surface 70 may include only the inclined surface 74.

The trench 50 includes the trench wall surface 70 between the trench open end 52E and the curved surface 56. This allows the depth D1 of the trench 50 (refer to FIG. 3) and the radius of curvature R1 of the curved surface 56 (refer to FIG. 3) to be easily set at the desired values.

As illustrated in FIG. 12, when the trench wall surface 70 includes the inclined surface 74, the projection width W2 of the projection 66 may be set to be less than or equal to distance W3 spanning the curved surface 56 from a connection point P of the curved surface 56 and the trench bottom surface 54 to the trench open end 52E in plan view. Although not illustrated in detail, the trench 50 of FIG. 13 may also be formed to satisfy the relationship of W2≤W3. Further, the trench 50 of FIG. 11 or the trench 50 of the first embodiment may be formed to satisfy the relationship of W2≤W3. In this manner, the projection width W2 is limited at distance W3 to increase the electric field mitigation effect.

Table 1 illustrates an example of the measurement of the maximum electric field applied to the curved surface 56 when varying the projection width W2 of the projection 66 and the depth D1 of the trench 50 in the trench 50 of FIG. 11 that includes the vertical surface 72 as the trench wall surface 70. In this case, the gate voltage was, for example, 10V. The projection width W2 was varied to be 0 nm, 50 nm, and 100 nm. The depth D1 was varied to be 10 nm, 30 nm, and 50 nm. The radius of curvature R1 of the curved surface 56 was, for example, 5 nm.

TABLE 1

| Maximum Electric Field | Trench Depth: | Trench Depth: | Trench Depth: |
|---|---|---|---|
| (a.u.) | 10 nm | 30 nm | 50 nm |
| Projection Width: 0 nm | 5.18 | 5.16 | 5.13 |
| Projection Width: 50 nm | 5.54 | 5.81 | 5.75 |
| Projection Width: 100 nm | 5.65 | 5.88 | 6.18 |

Table 2 illustrates an example of the measurement of the maximum electric field applied to the curved surface 56 when varying the projection width W2 of the projection 66 and the depth D1 of the trench 50 under the same conditions as Table 1 in the trench 50 of FIG. 12 that includes the inclined surface 74 having inclination angle 60° as the trench wall surface 70.

TABLE 2

| Maximum Electric Field | Trench Depth: | Trench Depth: | Trench Depth: |
|---|---|---|---|
| (a.u.) | 10 nm | 30 nm | 50 nm |
| Projection Width: 0 nm | 5.14 | 5.33 | 5.28 |
| Projection Width: 50 nm | 5.55 | 5.76 | 5.60 |
| Projection Width: 100 nm | 5.67 | 5.83 | 5.53 |

Table 3 illustrates an example of the measurement of the maximum electric field applied to the curved surface 56 when varying the projection width W2 of the projection 66 and the depth D1 of the trench 50 under the same conditions as Table 1 in the trench 50 of FIG. 13 that includes the inclined surface 74 having inclination angle 30° as the trench wall surface 70.

TABLE 3

| Maximum Electric Field | Trench Depth: | Trench Depth: | Trench Depth: |
|---|---|---|---|
| (a.u.) | 10 nm | 30 nm | 50 nm |
| Projection Width: 0 nm | 4.89 | 4.88 | 4.60 |
| Projection Width: 50 nm | 5.69 | 5.55 | 5.56 |
| Projection Width: 100 nm | 5.69 | 5.62 | 5.71 |

When acquiring the maximum electric field (approximately 5.69), which was measured at region F2 in the vicinity of the electrode end 240E of the nitride semiconductor device 100 of FIG. 6 having no trench structure, as the reference value Ref for comparison, the maximum electric field illustrated in Tables 1 to 3 were all less than the reference value Ref when the projection width W2 was 0 nm. Further, the maximum electric field was less than the reference value Ref depending on the combination of the projection width W2 and the depth D1. The maximum electric field with the inclined surface 74 tended to be lower than that with the vertical surface 72, and the maximum electric field tended to be lower when the inclination angle of the inclined surface 74 was 60° than when the inclination angle was 30°.

Accordingly, the nitride semiconductor device 10 of the second embodiment has the same advantages as the first embodiment.

### MODIFIED EXAMPLES

The above embodiments may be modified as described below. The above-described embodiments and the modified examples described below may be combined as long as there is no technical contradiction.

In each of the above embodiments, the nitride semiconductor device 10 is a normally-off type nitride semiconductor HEMT but may be a normally-on type nitride semiconductor HEMT.

In each of the above embodiments, the nitride semiconductor device 10 is a HEMT using gallium nitride but may be a HEMT using another group-III nitride semiconductor.

In the second embodiment, the radius of curvature R1 of the curved surface 56 may be changed in the same manner as the first embodiment.

In this specification, the word “on” includes the meaning of “above” in addition to the meaning of “on” unless otherwise described in the context. Accordingly, the phrase of “first layer formed on second layer” may mean that the first layer is formed directly contacting the second layer in one embodiment and that the first layer is located above the second layer without contacting the second layer in another embodiment. Thus, the word “on” will also allow for a structure in which another layer is located between the first layer and the second layer. For example, each of the above embodiments in which the electron supply layer 18 is formed on the electron transit layer 16 includes a structure in which an intermediate layer (e.g., spacer layer or another layer) is located between the electron supply layer 18 and the electron transit layer 16 to stably form the 2 DEG 20.

The Z-axis direction as referred to in this specification does not necessarily have to be the vertical direction and does not necessarily have to fully coincide with the vertical direction. Accordingly, in the structures disclosed above (e.g., structure illustrated in FIG. 1), upward and downward in the Z-axis direction as referred to in this specification is not limited to upward and downward in the vertical direction. For example, the X-axis direction may be the vertical direction. Alternatively, the Y-axis direction may be the vertical direction.

The terms used in this specification to indicate directions such as vertical, horizontal, upward, downward, up, down, forward, rearward, side, left, right, front, and back will be attributed to specific directions of the described and illustrated device. In this disclosure, a variety of alternative directions may be available for any given direction. Thus, directional terms should not be construed narrowly.

### Clauses

Technical concepts that can be understood from each of the above embodiments and modified examples will now be described. The reference characters used to denote elements of the embodiments are illustrated in parenthesis for the corresponding elements of the clauses described below. The reference characters are given as examples to aid understanding and not intended to limit elements to the elements denoted by the reference characters.

### [Clause A1]

A nitride semiconductor device (10), including:
an electron transit layer (16) composed of a nitride semiconductor;
an electron supply layer (18) composed of a nitride semiconductor having a larger band gap than the electron transit layer (16) and disposed on the electron transit layer (16) to generate two-dimensional electron gas (20) in the electron transit layer (16);
a gate layer (22) composed of a nitride semiconductor containing acceptor impurities and disposed on the electron supply layer (18); and
a gate electrode (24) contacting the gate layer (22);
a source electrode (32) and a drain electrode (34) that are electrically connected to the two-dimensional electron gas (20), where
the gate layer (22) includes a trench (50) that is recessed from an upper surface (22S) of the gate layer (22) in a region contacting the gate electrode (24),
the trench (50) includes
   a trench open end (52E),
   a trench bottom surface (54), and
   a curved surface (56: 56A; 56B) continuous with the trench bottom surface (54) and curved from the trench bottom surface (54) toward the trench open end (52E).

### [Clause A2]

The nitride semiconductor device (10) according to clause A1, where
the trench open end (52E) includes a first edge (52EA) and a second edge (52EB) that face each other in a first direction,
the trench (50) has a trench width (W1) corresponding to a distance between the first edge (52EA) and the second edge (52EB) in the first direction,
the gate electrode (24) has a gate electrode length (L1) in the first direction, and
the trench width (W1) is less than or equal to the gate electrode length (L1).

### [Clause A3]

The nitride semiconductor device (10) according to clause A1 or A2, where
the gate electrode (24) includes
   a lower electrode portion (64) filling the trench (50), and
   an upper electrode portion (62) formed integrally with the lower electrode portion (64) and located upward from an upper surface position of the gate layer (22), and
the upper electrode portion (62) includes a side surface (62S) that is flatly continuous with an outer surface (64S) of the lower electrode portion (64) at where the trench open end (52E) is located.

### [Clause A4]

The nitride semiconductor device (10) according to clause A1 or A2, where
the gate electrode (24) includes
   a lower electrode portion (64) filling the trench (50), and
   an upper electrode portion (62) formed integrally with the lower electrode portion (64) and located upward from an upper surface position of the gate layer (22), and
   the upper electrode portion (62) includes a projection (66: 66A; 66B) projecting sideways from the trench open end (52E) along an upper surface of the gate layer (22).

### [Clause A5]

The nitride semiconductor device (10) according to clause A4, where the projection (66: 66A; 66B) projects sideways from the trench open end (52E) along the upper surface of the gate layer (22) over a projection width (W2) that is less than or equal to a depth (D1) of the trench (50).

### [Clause A6]

The nitride semiconductor device (10) according to clause A5, where the projection width (W2) is less than or equal to a distance (W3) spanning the curved surface (56: 56A; 56B) from a connection point of the curved surface (56: 56A; 56B) and the trench bottom surface (54) to the trench open end (52E) in plan view.

### [Clause A7]

The nitride semiconductor device (10) according to clause A4, where the projection (66: 66A; 66B) projects sideways from the trench open end (52E) along the upper surface of the gate layer (22) over a projection width (W2) that is greater than 0 nm and less than or equal to 100 nm.

### [Clause A8]

The nitride semiconductor device (10) according to any one of clauses A1 to A6, where the trench (50) includes a trench wall surface (70) connecting the trench open end (52E) and the curved surface (56: 56A; 56B).

### [Clause A9]

The nitride semiconductor device (10) according to clause A8, where the trench wall surface (70) includes an inclined surface (74).

### [Clause A10]

The nitride semiconductor device (10) according to clause A9, where the inclined surface (74) has an inclination angle of 30° or greater and 600 or less.

### [Clause A11]

The nitride semiconductor device (10) according to clause A9 or A10, where the trench wall surface (70) further includes a second curved surface (76) between the inclined surface (74) and the trench open end (52E).

### [Clause A12]

The nitride semiconductor device (10) according to any one of clauses A8 to A10, where the trench wall surface (70) includes a vertical surface (72).

### [Clause A13]

The nitride semiconductor device (10) according to clause A12, where the trench wall surface (70) further includes a second curved surface (76) between the vertical surface (72) and the trench open end (52E).

### [Clause A14]

The nitride semiconductor device (10) according to any one of clauses A1 to A13, where the trench (50) has a depth of 10 nm or greater and 50 nm or less.

### [Clause A15]

The nitride semiconductor device (10) according to any one of clauses A1 to A14, where the curved surface (56; 56A; 56B) has a radius of curvature (R1) of 10 nm or greater and 30 nm or less.

### [Clause A16]

The nitride semiconductor device (10) according to any one of clauses A1 to A15, where
the electron transit layer (16) is a GaN layer,
the electron supply layer (18) is an AlGaN layer, and
the gate layer (22) is a GaN layer containing the acceptor impurities.

Exemplary descriptions are given above. In addition to the elements and methods (manufacturing processes) described to illustrate the technology of this disclosure, a person skilled in the art would recognize the potential for a wide variety of combinations and substitutions. All replacements, modifications, and variations within the scope of the claims are intended to be encompassed in the present disclosure.

1. A nitride semiconductor device, comprising:
an electron transit layer composed of a nitride semiconductor;
an electron supply layer composed of a nitride semiconductor having a larger band gap than the electron transit layer and disposed on the electron transit layer to generate two-dimensional electron gas in the electron transit layer;
a gate layer composed of a nitride semiconductor containing acceptor impurities and disposed on the electron supply layer;
a gate electrode contacting the gate layer; and
a source electrode and a drain electrode that are electrically connected to the two-dimensional electron gas, wherein
the gate layer includes a trench that is recessed from an upper surface of the gate layer in a region contacting the gate electrode,
the trench includes
a trench open end,
a trench bottom surface, and
a curved surface continuous with the trench bottom surface and curved from the trench bottom surface toward the trench open end.

2. The nitride semiconductor device according to claim 1, wherein
the trench open end includes a first edge and a second edge that face each other in a first direction,
the trench has a trench width corresponding to a distance between the first edge and the second edge in the first direction,
the gate electrode has a gate electrode length in the first direction, and
the trench width is less than or equal to the gate electrode length.

3. The nitride semiconductor device according to claim 1, wherein
the gate electrode includes
a lower electrode portion filling the trench, and
an upper electrode portion formed integrally with the lower electrode portion and located upward from an upper surface position of the gate layer, and
the upper electrode portion includes a side surface that is flatly continuous with an outer surface of the lower electrode portion at where the trench open end is located.

4. The nitride semiconductor device according to claim 1, wherein
the gate electrode includes
a lower electrode portion filling the trench, and
an upper electrode portion formed integrally with the lower electrode portion and located upward from an upper surface position of the gate layer, and
the upper electrode portion includes a projection projecting sideways from the trench open end along the upper surface of the gate layer.

5. The nitride semiconductor device according to claim 4, wherein the projection projects sideways from the trench open end along the upper surface of the gate layer over a projection width that is less than or equal to a depth of the trench.

6. The nitride semiconductor device according to claim 4, wherein the projection projects sideways from the trench open end along the upper surface of the gate layer over a projection width that is greater than 0 nm and less than or equal to 100 nm.

7. The nitride semiconductor device according to claim 1, wherein the trench includes a trench wall surface connecting the trench open end and the curved surface.

8. The nitride semiconductor device according to claim 7, wherein the trench wall surface includes an inclined surface.

9. The nitride semiconductor device according to claim 8, wherein the inclined surface has an inclination angle of 30° or greater and 600 or less.

10. The nitride semiconductor device according to claim 7, wherein the trench wall surface includes a vertical surface.

11. The nitride semiconductor device according to claim 1, wherein the trench has a depth of 10 nm or greater and 50 nm or less.

12. The nitride semiconductor device according to claim 1, wherein the curved surface has a radius of curvature of 10 nm or greater and 30 nm or less.

13. The nitride semiconductor device according to claim 1, wherein
the electron transit layer is a GaN layer,
the electron supply layer is an AlGaN layer, and
the gate layer is a GaN layer containing the acceptor impurities.
